(19) United States
(12) Patent Application Publication
(10) Pub. No.: US 2025/0198219 A1
(43) Pub. Date: Jun. 19, 2025

(54) DOOR PART USED IN SEMICONDUCTOR SUBSTRATE PROCESSING DEVICE

(71) Applicant: YEST CO., LTD., Pyeongtaek-si (KR)

(72) Inventors: Young Joon Ham, Pyeongtaek-si (KR); Jeong Eui Kim, Incheon (KR); Yong Hwan Kwon, Yongin-si (KR); Jin Seok Lee, Pyeongtaek-si (KR); Jong Hwan Baek, Pyeongtaek-si (KR)

(21) Appl. No.: 18/824,648

(22) Filed: Sep. 4, 2024

(30) Foreign Application Priority Data
Dec. 13, 2023 (KR) 10-2023-0180421

(51) Int. Cl. E05F 15/70; H01L 21/67

(52) U.S. Cl. CPC E05F 15/70; H01L 21/67109; E05Y 2999/00

(57) ABSTRACT

A door part used in a semiconductor substrate processing device includes a first flange on which a loader accommodating a wafer is placed, a second flange connected to a lower portion of the first flange, a caught protrusion part extending downward from an edge of the first flange, a door disposed below the second flange, and a guide connected to an upper surface of the door and in which a groove corresponding to a shape of at least a portion of the caught protrusion part is formed so that the caught protrusion part sits on the groove, in which the caught protrusion part is unseated from the groove of the guide depending on a height between the first flange and the door, and the door is rotatable when the caught protrusion part is unseated from the groove.

### CROSS-REFERENCE TO RELATED APPLICATIONS

This application claims the priority benefit of Korean Patent Application No. 10-2023-0180421, filed on Dec. 13, 2023, in the Korean Intellectual Property Office, the entire disclosure of which is incorporated herein by reference for all purposes.

### FIELD OF THE DISCLOSURE

One or more embodiments relate to a door part used in a semiconductor substrate processing device.

### BACKGROUND

Process gas used in semiconductor substrate processing is often toxic or combustible, and a semiconductor substrate processing device must be properly controlled to prevent leakage from a chamber on which a process is performed. More caution is required in a semiconductor substrate processing device that processes a wafer with high-pressure process gas, and leakage is especially likely to occur at a door, which is the point where a semiconductor substrate is accommodated in a chamber and taken out. For example, Korean Patent Application Publication No. 10-2465578 discloses an automatic chamber door opening device.

### SUMMARY

The purpose of an embodiment is to provide a door part that may not rotate when a caught protrusion part sits on a groove and may control the position of a door.

The purpose of an embodiment is to provide a door part that may prevent safety accidents by determining whether a caught protrusion part is in the correct position.

The purpose of an embodiment is to provide a door part that may apply force to a process chamber, so the process chamber is closed and sealed.

According to various embodiments, a door part used in a semiconductor substrate processing device includes a first flange on which a loader accommodating a wafer is placed, a second flange connected to a lower portion of the first flange, a caught protrusion part extending downward from an edge of the first flange, a door disposed below the second flange, and a guide connected to an upper surface of the door and in which a groove corresponding to a shape of at least a portion of the caught protrusion part is formed so that the caught protrusion part sits on the groove, in which the caught protrusion part is unseated from the groove of the guide depending on a height between the first flange and the door, and the door is rotatable when the caught protrusion part is unseated from the groove.

According to an embodiment, the first flange and the second flange may be connected to each other while maintaining a first height when the caught protrusion part sits on the groove, and the door may be pressed toward the first flange so that the first flange and the second flange are connected to each other at a second height that is less than the first height.

According to an embodiment, the caught protrusion part may include a first stem protruding from the edge of the first flange, a second stem extending downward from one end of the first stem, and a caught protrusion fixed to the second stem, in which the caught protrusion may sit on the groove formed in the guide.

According to an embodiment, the guide may include a first part disposed in the door and the upper surface of the door, a second part extending upward from one end of the first part, and a third part extending from one end of the second part toward the caught protrusion part, in which the groove may be formed in the third part so that the caught protrusion part sits on the groove.

According to an embodiment, the door part may include the caught protrusion part in plurality and the guide in plurality.

According to an embodiment, the door part may further include a positioning sensor installed on the guide and configured to identify a position of the caught protrusion part and a controller configured to determine whether the caught protrusion part is in a correct position based on a measured value from the positioning sensor.

According to various embodiment, a semiconductor substrate processing device includes a process chamber, an external chamber surrounding the process chamber, and a door part disposed below the process chamber and capable of moving vertically, in which the door part includes a first flange on which a loader accommodating a wafer is placed, a second flange connected to a lower portion of the first flange, a caught protrusion part extending downward from an edge of the first flange, a door disposed below the second flange, and a guide connected to an upper surface of the door and in which a groove corresponding to a shape of at least a portion of the caught protrusion part is formed so that the caught protrusion part sits on the groove, in which the caught protrusion part is unseated from the groove of the guide when the door part and the process chamber are in close contact with each other, and the door is rotatable when the caught protrusion part is unseated from the groove.

According to an embodiment, the first flange and the second flange may be connected to each other while maintaining a first height when the caught protrusion part sits on the groove, and the door may be pressed toward the process chamber so that the first flange and the second flange are connected to each other at a second height that is less than the first height.

According to an embodiment, the caught protrusion part may include a first stem protruding from the edge of the first flange, a second stem extending downward from one end of the first stem, and a caught protrusion fixed to the second stem, in which the guide may include a first part disposed in the door and the upper surface of the door, a second part extending upward from one end of the first part, and a third part extending from one end of the second part toward the caught protrusion, in which the groove may be formed in the third part so that the caught protrusion sits on the groove.

According to an embodiment, the door part may further include a positioning sensor installed on the guide and configured to identify a position of the caught protrusion part and a controller configured to determine whether the caught protrusion part is in a correct position based on a measured value from the positioning sensor.

Additional aspects of embodiments will be set forth in part in the description which follows and, in part, will be apparent from the description, or may be learned by practice of the disclosure.

According to an embodiment, a door part may not rotate when a caught protrusion part sits on a groove and may control the position of a door.

According to an embodiment, a door part may prevent safety accidents by determining whether a caught protrusion part is in the correct position.

According to an embodiment, a door part may apply force to a process chamber, so the process chamber may be closed and sealed.

The effects of the door part are not limited to the above-mentioned effects, and other unmentioned effects can be clearly understood from the above description by those having ordinary skill in the technical field to which the present disclosure pertains.

### BRIEF DESCRIPTION OF THE DRAWINGS

FIG. 1 is a cross-sectional view of a semiconductor substrate processing device according to an embodiment;

FIG. 2 is a perspective view of the semiconductor substrate processing device according to an embodiment;

FIG. 3 is a perspective view of a door part according to an embodiment;

FIG. 4 is a cross-sectional view of the door part according to an embodiment;

FIGS. 5A and 5B are a cross-sectional view and a side view of a portion of the door part, according to an embodiment; and

FIGS. 6A and 6B are a cross-sectional view and a side view of a portion of the door part, according to an embodiment.

### DETAILED DESCRIPTION

Hereinafter, embodiments will be described in detail with reference to the accompanying drawings. However, various alterations and modifications may be made to the embodiments. Here, the embodiments are not construed as limited to the disclosure. The embodiments should be understood to include all changes, equivalents, and replacements within the idea and the technical scope of the disclosure.

The terminology used herein is for the purpose of describing particular embodiments only and is not to be limiting of the embodiments. The singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which the embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

When describing the embodiments with reference to the accompanying drawings, like reference numerals refer to like components and a repeated description related thereto will be omitted. In the description of embodiments, detailed description of well-known related structures or functions will be omitted when it is deemed that such description will cause ambiguous interpretation of the present disclosure.

Also, in the description of the components, terms such as first, second, A, B, (a), (b) or the like may be used herein when describing components of the present disclosure. These terms are used only for the purpose of discriminating one component from another component, and the nature, the sequences, or the orders of the components are not limited by the terms. It should be noted that if one component is described as being “connected,” “coupled” or “joined” to another component, the former may be directly “connected,” “coupled,” and “joined” to the latter or “connected”, “coupled”, and “joined” to the latter via another component.

A component, which has the same common function as a component included in any one embodiment, will be described by using the same name in other embodiments. Unless disclosed to the contrary, the description of any one embodiment may be applied to other embodiments, and the specific description of the repeated configuration will be omitted.

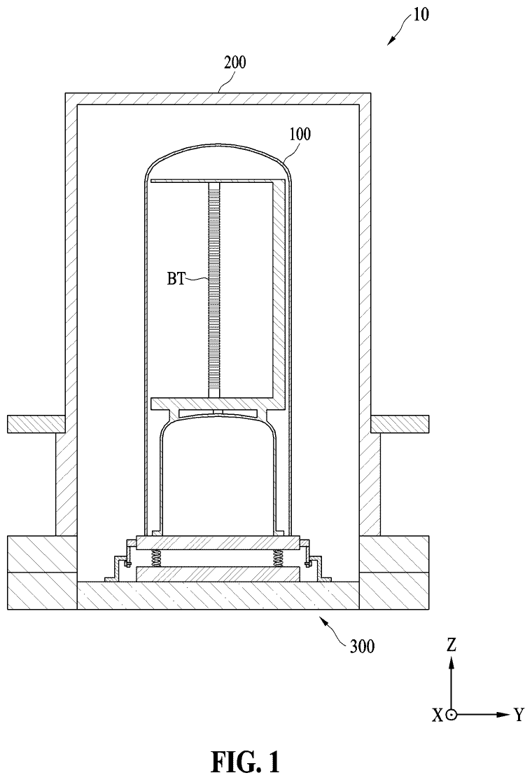

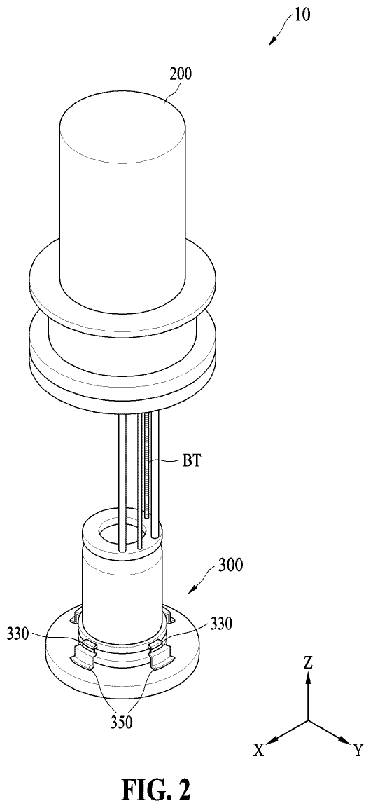

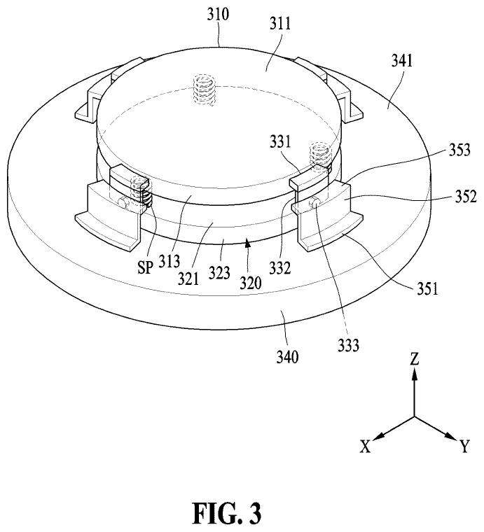

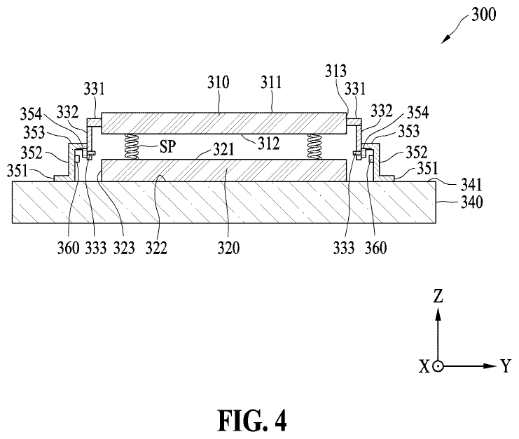

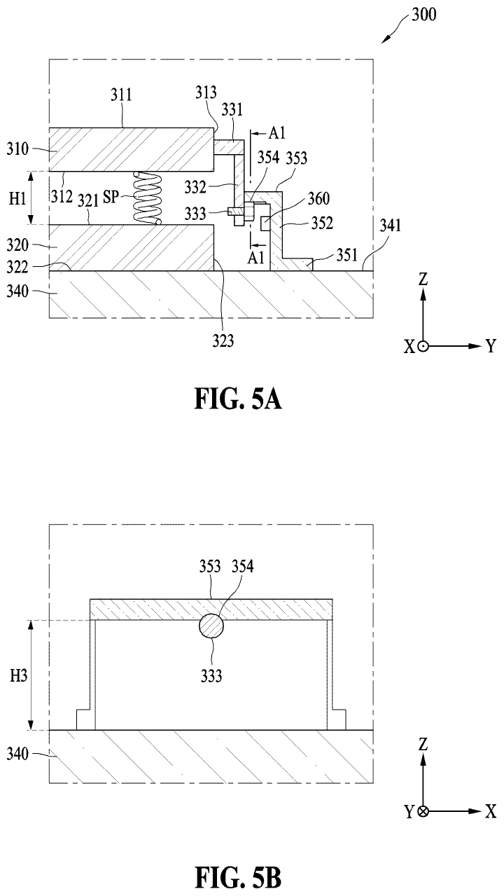

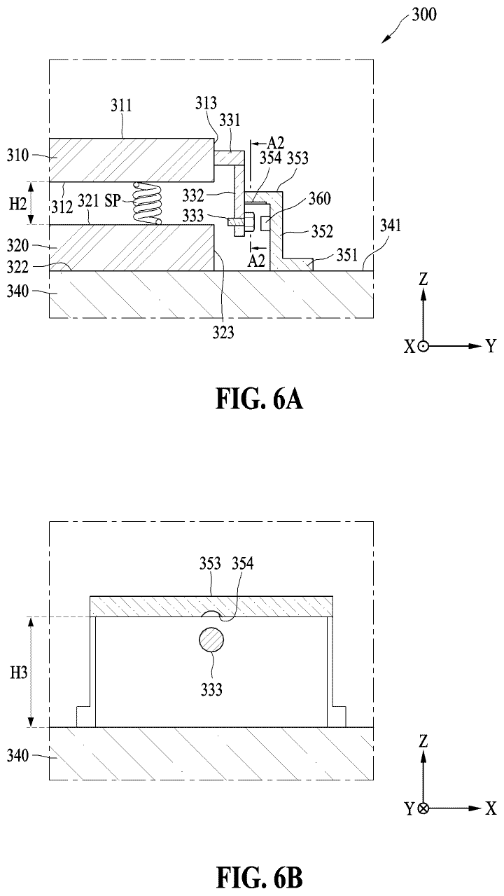

FIG. 1 is a cross-sectional view of a semiconductor substrate processing device 10, according to an embodiment. FIG. 2 is a perspective view of the semiconductor substrate processing device 10 according to an embodiment. FIG. 3 is a perspective view of a door part 300 according to an embodiment. FIG. 4 is a cross-sectional view of the door part 300 according to an embodiment. FIGS. 5A and 5B are a cross-sectional view and a side view of a portion of the door part 300, according to an embodiment. FIGS. 6A and 6B are a cross-sectional view and a side view of a portion of the door part 300, according to an embodiment.

Referring to FIG. 1, in an embodiment, the semiconductor substrate processing device 10 may include a process chamber 100, an external chamber 200 surrounding the process chamber 100, and the door part 300 disposed below the process chamber 100 (e.g., the −Z direction the process chamber 100 faces in FIG. 1) and movable vertically (e.g., the +/−Z direction in FIG. 1).

According to an embodiment, a wafer may be accommodated in the process chamber 100. The wafer may be accommodated and processed in the process chamber 100. In particular, a process of processing the wafer in a high-pressure gas atmosphere may be performed in the process chamber 100. For example, a high-pressure heat treatment process may be performed on the wafer in the process chamber 100 using hydrogen or deuterium gas. Here, the wafer may enter the lower side of the process chamber 100 through an opening. The wafer may move in the process chamber 100 while being accommodated in the door part 300 that is disposed below the process chamber 100 and movable vertically.

According to an embodiment, process gas injected into the process chamber 100 at high pressure may be toxic and/or combustible. When gas in the process chamber 100 leaks out of the process chamber 100, there may be a risk of explosion or a safety accident, so the process chamber 100 may need to be properly closed or sealed. In particular, the door part 300, which opens or closes the process chamber 100, and a surrounding portion of the door part 300 may have an inherent risk of leakage of high-pressure process gas, so the process chamber 100 may need to be more properly closed or sealed to prevent leakage of process gas, and the door part 300 may also need to be properly controlled.

The external chamber 200 according to an embodiment may be disposed to surround the process chamber 100. The external chamber 200 and the process chamber 100 may have a dual chamber structure. Purge gas may be injected into a space between the external chamber 200 and the process chamber 100. For example, inert gas, such as nitrogen gas, may be injected into the space. In particular, purge gas may be injected into the space at pressure higher than high-pressure process gas in the process chamber 100. When pressure of the space between the external chamber 200 and the process chamber 100 is higher than pressure in the process chamber 100, the process gas in the process chamber 100 may not leak to the outside of the semiconductor substrate processing device 10. A heater (not shown) may be disposed between the external chamber 200 and the process chamber 100. The heater may perform heat treatment on the wafer accommodated in the process chamber 100.

Referring to FIGS. 1 and 2, in an embodiment, the door part 300 may be disposed below the process chamber 100 and may move vertically (e.g., +/−Z direction in FIG. 2). In particular, FIG. 1 shows a state in which the door part 300 of the semiconductor substrate processing device 10 ascends so that a loader (BT) on which the wafer is loaded is accommodated in the process chamber 100, whereas FIG. 2 shows a state in which the door part 300 descends so that the BT, on which the wafer is loaded, is positioned outside of the process chamber 100.

The door part 300 according to an embodiment may lock or unlock the process chamber 100 by performing a rotation operation. For example, the door part 300 may lock and seal the process chamber 100 by performing the rotation operation in the clockwise (or counterclockwise) direction after ascending from below the process chamber 100, may then unlock the process chamber 100 by performing the rotation operation in the counterclockwise (or clockwise) direction, and may open the process chamber 100 by descending downward from the process chamber 100. Since the door part 300 may open or close the process chamber 100 through the rotation operation, the rotation operation of the door part 300 may need to be controlled. The door part 300 may control the rotation operation of the door part 300 using a caught protrusion part 330 and a groove 354 of a guide 350 to be described below and may prevent safety accidents caused by the ascending and descending of the door part 300.

According to an embodiment, the BT on which the wafer is loaded may be placed in the door part 300. The BT may be installed in the upper side of the door part 300. For example, the BT may be installed on an upper surface 311 of a first flange of the door part 300 to be described below. The wafer loaded on the BT may be accommodated in the process chamber 100 and discharged according to the ascending and descending of the door part 300.

Referring back to FIG. 2, in an embodiment, the door part 300 may include the caught protrusion part 330 and the guide 350 on which the caught protrusion part 330 sits. Here, the door part 300 may include the caught protrusion part 330 in plurality and the guide 350 in plurality in plurality and may particularly include the caught protrusion parts 330 and the guides 350 in an equal number. For example, in FIG. 2, the door part 300 may include four caught protrusion parts 330 and four guides 350.

Referring to FIGS. 3 and 4, in an embodiment, the door part 300 may include a first flange 310 on which the BT accommodating the wafer is placed, a second flange 320 connected to the lower portion of the first flange 310, the caught protrusion part 330 extending downward (e.g., the side in the −Z direction the first flange 310 faces in FIG. 3) from the edge of the first flange 310, a door 340 disposed below (e.g., the side in the −Z direction the second flange 320 faces in FIG. 3) the second flange 320, and the guide 350 connected to the upper surface of the door 340 and in which a groove (e.g., the groove 354 in FIG. 6) corresponding to a shape of at least a portion of the caught protrusion part 330 is formed so that the caught protrusion part 330 sits on the groove.

The first flange 310 according to an embodiment may include the upper surface 311, a lower surface 312 that is opposite to the upper surface 311, and a side surface 313 between the upper surface 311 and the lower surface 312.

The second flange 320 according to an embodiment may include an upper surface 321, a lower surface 322 that is opposite to the upper surface 321, and a side surface 323 between the upper surface 321 and the lower surface 322.

According to an embodiment, a spring SP may be disposed between the first flange 310 and the second flange 320. For example, the SP may be connected to at least one of the lower surface 312 of the first flange 310 and the upper surface 321 of the second flange 320, and preferably, may be connected to at least the upper surface 321 of the second flange 320. The length of the SP may be tensioned or compressed depending on the height between the first flange 310 and the second flange 320. The SP may allow the first flange 310 and/or the second flange 320 to apply force in one direction when the height between the first flange 310 and the second flange 320 becomes less than a first height H1. For example, when the height between the first flange 310 and the second flange 320 decreases from the first height H1 in FIG. 5 to a second height H2 in FIG. 6, the first flange 310 may apply force in the +Z direction of FIGS. 5 and 6. Here, the applied force may help the first flange 310 to strongly seal and close the process chamber 100.

The door 340 according to an embodiment may rotate independently from the second flange 320. For example, the second flange 320 may be fixed without being rotated, and the door 340 may rotate in the clockwise and/or counterclockwise direction. The second flange 320, the first flange 310 connected to the second flange 320, and the caught protrusion part 330 extending from the first flange 310 may be fixed, and the door 340 and the guide 350 connected to an upper surface 341 of the door 340 may rotate in the clockwise and/or counterclockwise direction. Since only the door 340 may rotate independently from the first flange 310 and the second flange 320, the BT may lock the process chamber 100 by performing the rotation operation without being rotated, and the wafer may be stably accommodated in the process chamber 100 and discharged.

The caught protrusion part 330 according to an embodiment may be unseated from a groove (e.g., the groove 354 in FIG. 6) of the guide 350 depending on the height between the first flange 310 and the door 340. The door 340 may rotate when the caught protrusion part 330 is unseated from the groove 354. In contrast, the caught protrusion part 330 may not rotate when the caught protrusion part 330 sits on the groove 354 of the guide 350. Whether the door 340 may rotate may be determined depending on whether the caught protrusion part 330 sits on the groove 354 of the guide 350. A detailed description of whether the caught protrusion part 330 sits on the groove 354 of the guide 350 depending on the height between the first flange 310 and the door 340 is provided below with reference to FIGS. 5 and 6.

In an embodiment, the caught protrusion part 330 may include a first stem 331 protruding from the edge of the first flange 310, a second stem 332 extending downward (e.g., the side in the −Z direction the first stem 331 faces in FIGS. 3 and 4) from one end of the first stem 331, and a caught protrusion 333 fixed to the second stem 332, in which the caught protrusion 333 may sit on the groove 354 formed in the guide 350.

The first stem 331 according to an embodiment is the edge of the first flange 310 and may protrude from the side surface 313 of the first flange 310. However, the first stem 331 may also protrude from the upper surface 311 of the first flange 310 when the first stem 331 is the edge of the first flange 310. However, in this case, the first stem 331 should protrude from the upper surface 311 of the first flange 310 in a direction that is parallel to the upper surface 311 of the first flange 310 so that the second stem 332 may extend downward from one end of the first stem 331. That is, the first stem 331 may protrude by being inclined with the upper surface 311 of the first flange 310 to extend downward from one end of the first stem 331 without interference from the first flange 310.

According to an embodiment, a through hole may be formed in the second stem 332. Preferably, the through hole may be formed below the second stem 332.

The caught protrusion 333 according to an embodiment may include a bolt-shaped structure including a head and a body. Here, the diameter of the through hole of the second stem 332 may be greater than the diameter of the body included in the bolt-shaped structure and less than the diameter of the head included in the bolt-shaped structure. The body included in the bolt-shaped structure may be inserted into the through hole of the second stem 332, and the caught protrusion 333 may be fixed to the second stem 332. In another embodiment, the second stem 332 and the caught protrusion 333 may be formed integrally without being assembled with each other. The head included in the bolt-shaped structure may sit on the groove 354 formed in the guide 350.

In an embodiment, the guide 350 may include a first part 351 fastened to the door 340 and the upper surface 341 of the door 340, a second part 352 extending upward (e.g., the side in the +Z direction the guide 350 faces in FIGS. 3 and 4) from one end of the first part 351, and a third part 353 extending from one end of the second part 352 toward the caught protrusion part 330, in which the groove 354 may be formed in the third part 353 so that the caught protrusion part 330 may sit on the groove 354.

The second part 352 according to an embodiment may extend from one end of the first part 351 in a direction that is perpendicular to the first part 351 (e.g., the +Z direction in FIGS. 3 and 4). The second part 352 may extend to a height that is less than the height of the first stem 331 of the caught protrusion part 330.

The third part 353 according to an embodiment may extend in a horizontal direction (e.g., the direction that is parallel to the XY plane in FIGS. 3 and 4) toward the second stem 332. The third part 353 may extend to avoid contacting the second stem 332. The groove 354 formed in the third part 353 may have a semicircular shape that is recessed upwardly (e.g., the side in the +Z direction the third part 353 faces in FIGS. 3 and 4). The groove 354 formed in the third part 353 may correspond to the head included in the bolt-shaped structure included in the caught protrusion 333.

In an embodiment, the door part 300 may include the caught protrusion part 330 in plurality and the guide 350 in plurality. For example, the door part 300 of FIG. 4 may include the four caught protrusion parts 330 and the four guides 350. The caught protrusion parts 330 and the guides 350 may correspond to each other one by one, and the number thereof may be equal.

In an embodiment, the door part 300 may include a positioning sensor 360 installed on the guide 350 and configured to identify the position of the caught protrusion part 330 and a controller (not shown) configured to determine whether the caught protrusion part 330 is in the correct position based on a measured value from the positioning sensor 360. The positioning sensor 360 may be installed on the guide 350 or the caught protrusion part 330.

FIGS. 3 and 4 show the caught protrusion part 330 in the correct position. The caught protrusion part 330 may be spaced apart only in the vertical direction (e.g., +/−Z direction in FIGS. 3 and 4) even when the caught protrusion part 330 sits on or is unseated from the groove 354 of the guide 350, so when the caught protrusion part 330 ascends or descends, it may be defined that the caught protrusion part 330 is in the correct position when the caught protrusion part 330 is capable of sitting on the groove 354 of the guide 350. When the door 340 rotates in the clockwise and/or counterclockwise direction by performing the rotation operation, the caught protrusion part 330 may not sit on the groove 354 of the guide 350 or may not sit on the groove 354 of the guide 350 even when the caught protrusion part 330 ascends or descends vertically, so it may be defined that the caught protrusion part 330 is not in the correct position.

The controller according to an embodiment may determine whether the caught protrusion part 330 is in the correct position with respect to the door 340, may prevent safety accidents by preventing the door part 300 from ascending and descending when the caught protrusion part 330 is out of the correct position, and may control the position of the door 340. For example, the controller may prevent the door part 300 from ascending and descending when the door part 300 performs the rotation operation on the door 340 to unlock the process chamber 100, but the caught protrusion part 330 is not in the correct position due to too little and/or too much rotation. In this case, the ascending and descending of the door 300 may be allowed only when the caught protrusion part 330 sits on the groove 354 of the guide 350.

Referring to FIGS. 5 and 6, according to an embodiment, whether the caught protrusion 333 sits on the groove 354 of the guide 350 may be determined depending on the height between the door 340 and the first flange 310. FIG. 5A shows a state in which the lower surface 312 of the first flange 310 and the upper surface 321 of the second flange 320 are spaced apart by the first height H1, and FIG. 6A shows a state in which the lower surface 312 of the first flange 310 and the upper surface 321 of the second flange 320 are spaced apart by the second height H2. In addition, FIG. 5B is a cross-sectional view taken along the A1-A1 line in FIG. 5A, showing that the caught protrusion part 330 sits on the groove 354 and is not escaping, and FIG. 6B is a cross-sectional view taken along the A2-A2 line in FIG. 6A, showing that the caught protrusion part 330 is unseated from the groove 354 and is escaping. As shown in FIG. 5B and FIG. 6B, third heights H3, which are the heights between the upper surface 341 of the door 340 and a position (e.g., the third part 353) in which the groove 354 of the guide 350 is formed, may be the same as each other.

Referring back to FIG. 5, the caught protrusion part 330 may sit on the groove 354 of the guide 350. For example, the caught protrusion 333 of the caught protrusion part 330 may sit on the groove 354. Since the caught protrusion part 330 sits on the groove 354, the rotation operation of the door 340 connected to the guide 350 may not be performed. Even when the controller determines that the caught protrusion part 330 is in the correct position with respect to the door 340 through the positioning sensor 360, the caught protrusion part 330 is physically caught in the groove 354, so the rotation operation of the door 340 may not be performed. Since the SP extends downward by the weight of the second flange 320 and the door 340, the groove 354 of the guide 350 connected to the door 340 may apply force downward from the caught protrusion part 330 so that the caught protrusion part 330 sits on the groove 354 and does not escape. Accordingly, the first height H1 may be maintained when the door par 300 ascends or descends.

Referring to FIG. 6, the first height H1 may not be maintained, and the SP may be compressed when the door part 300 reaches a position where the door part 300 no longer ascends. Accordingly, the height between the lower surface 312 of the first flange 310 and the upper surface 321 of the second flange 320 may decrease to the second height H2. That is, the first flange 310 and the second flange 320 may be close to each other. Even in this case, the third heights H3, which are the heights between the upper surface 341 of the door 340 and a position (e.g., the third part 353) in which the groove 354 of the guide 350 is formed, may be the same as each other, the groove 354 of the guide 350 may no longer apply force downward, so the caught protrusion part 330 may be unseated from the groove 354 and may escape. When the caught protrusion part 330 escapes from the groove 354, the door 340 may perform the rotation operation so that the door part 300 may lock or unlock the process chamber 100, and then the wafer may be accommodated or discharged in or from the process chamber 100 due to the ascending or descending of the door part 300.

Referring to FIGS. 1 to 6, in an embodiment, the door part 300 used in the semiconductor substrate processing device 10 may determine whether to rotate according to whether the caught protrusion part 330 sits on the groove 354, using the groove 354 of the guide 350 and the caught protrusion part 330, may control the position of the caught protrusion part 330, and may prevent safety accidents caused by the ascending and descending of the door part 300. In addition, the door part 300 may determine whether the caught protrusion part 330 is in the correct position and may apply force to the process chamber 100 so that the process chamber 100 may be closed and sealed.

While the embodiments are described with reference to drawings, it will be apparent to one of ordinary skill in the art that various alterations and modifications in form and details may be made in these embodiments without departing from the spirit and scope of the claims and their equivalents. For example, suitable results may be achieved if the described techniques are performed in a different order, and/or if components in a described system, architecture, device, or circuit are combined in a different manner, or replaced or supplemented by other components or their equivalents.

Therefore, other implementations, other embodiments, and equivalents of the claims are within the scope of the following claims.

1. A door part used in a semiconductor substrate processing device, the door part comprising:
a first flange on which a loader accommodating a wafer is placed;
a second flange connected to a lower portion of the first flange;
a caught protrusion part extending downward from an edge of the first flange;
a door disposed below the second flange; and
a guide connected to an upper surface of the door and in which a groove corresponding to a shape of at least a portion of the caught protrusion part is formed so that the caught protrusion part sits on the groove,
wherein the caught protrusion part is unseated from the groove of the guide depending on a height between the first flange and the door, and the door is rotatable when the caught protrusion part is unseated from the groove.

2. The door part of claim 1, wherein
the first flange and the second flange are connected to each other while maintaining a first height when the caught protrusion part sits on the groove, and
the door is pressed toward the first flange so that the first flange and the second flange are connected to each other at a second height that is less than the first height.

3. The door part of claim 1, wherein the caught protrusion part comprises:
a first stem protruding from the edge of the first flange;
a second stem extending downward from one end of the first stem; and
a caught protrusion fixed to the second stem,
wherein the caught protrusion sits on the groove formed in the guide.

4. The door part of claim 1, wherein the guide comprises:
a first part disposed in the door and the upper surface of the door;
a second part extending upward from one end of the first part; and
a third part extending from one end of the second part toward the caught protrusion part,
wherein the groove is formed in the third part so that the caught protrusion part sits on the groove.

5. The door part of claim 1, wherein the door part comprises the caught protrusion part in plurality and the guide in plurality.

6. The door part of claim 1, further comprising:
a positioning sensor installed on the guide and configured to identify a position of the caught protrusion part; and
a controller configured to determine whether the caught protrusion part is in a correct position based on a measured value from the positioning sensor.

7. A semiconductor substrate processing device comprising:
a process chamber;
an external chamber surrounding the process chamber; and
a door part disposed below the process chamber and capable of moving vertically,
wherein the door part comprises:
a first flange on which a loader accommodating a wafer is placed;
a second flange connected to a lower portion of the first flange;
a caught protrusion part extending downward from an edge of the first flange;
a door disposed below the second flange; and
a guide connected to an upper surface of the door and in which a groove corresponding to a shape of at least a portion of the caught protrusion part is formed so that the caught protrusion part sits on the groove,
wherein the caught protrusion part is unseated from the groove of the guide when the door part and the process chamber are in close contact with each other, and the door is rotatable when the caught protrusion part is unseated from the groove.

8. The semiconductor substrate processing device of claim 7, wherein
the first flange and the second flange are connected to each other while maintaining a first height when the caught protrusion part sits on the groove, and
the door is pressed toward the process chamber so that the first flange and the second flange are connected to each other at a second height that is less than the first height.

9. The semiconductor substrate processing device of claim 7, wherein the caught protrusion part comprises:
a first stem protruding from the edge of the first flange;
a second stem extending downward from one end of the first stem; and
a caught protrusion fixed to the second stem,
wherein the guide comprises:
a first part disposed in the door and the upper surface of the door;
a second part extending upward from one end of the first part; and
a third part extending from one end of the second part toward the caught protrusion,
wherein the groove is formed in the third part so that the caught protrusion sits on the groove.

10. The semiconductor substrate processing device of claim 7, wherein the door part further comprises:
a positioning sensor installed on the guide and configured to identify a position of the caught protrusion part; and
a controller configured to determine whether the caught protrusion part is in a correct position based on a measured value from the positioning sensor.
